(19) United States
(12) Patent Application Publication
(10) Pub. No.: US 2026/0057956 A1
(43) Pub. Date: Feb. 26, 2026

(54) CONTROLLER, STORAGE DEVICE AND METHOD FOR OPERATING STORAGE DEVICE

(71) Applicant: SK hynix Inc., Icheon-si (KR)

(72) Inventors: Jeong Myung LEE, Icheon-si (KR); Young Jin BAEK, Icheon-si (KR)

(21) Appl. No.: 19/018,225

(22) Filed: Jan. 13, 2025

(30) Foreign Application Priority Data
Aug. 22, 2024 (KR) 10-2024-0112461

(51) Int. Cl. G11C 29/52; G11C 29/02

(52) U.S. Cl. CPC G11C 29/52; G11C 29/022

(57) ABSTRACT

A storage device includes a memory including a plurality of word lines, a plurality of bit lines, and a plurality of memory cells; and a controller controlling a read operation on the memory, performing a first mutation operation of searching for a next read voltage using a first candidate read voltage when the read operation fails, and performing a second mutation operation of searching for the next read voltage using a second candidate read voltage when the read operation succeeds. The first candidate read voltage is obtained by applying a first offset value to a default read voltage used in the read operation, and the second candidate read voltage is obtained by applying a second offset value to the default read voltage.

### CROSS-REFERENCE TO RELATED APPLICATION

The present application claims priority under 35 U.S. C. § 119(a) to Korean Patent Application No. 10-2024-0112461 filed in the Korean Intellectual Property Office on Aug. 22, 2024, which is incorporated herein by reference in its entirety.

### BACKGROUND

### 1. Technical Field

Embodiments of the present disclosure generally relate to a controller, a storage device, and a method for operating a storage device.

### 2. Related Art

A storage device may include at least one memory which stores data. The storage device may include a controller which controls the operation of the at least one memory.

The controller may control an operation of writing data to the memory or reading or erasing data written to the memory on the basis of a command received from an external device.

When performing a read operation by the controller, data written to a memory cell included in the memory may be read using a preset read voltage. As the memory cell degrades, the read operation using the existing read voltage may fail, and due to this, the operational performance of the storage device may deteriorate.

### SUMMARY

Various embodiments of the present disclosure are directed to providing measures capable of improving the operational performance of a storage device by detecting the change of a read voltage due to degradation of a memory included in the storage device and setting in advance a read voltage.

In an embodiment, a storage device may include: a memory including a plurality of word lines, a plurality of bit lines, and a plurality of memory cells; and a controller configured to control a read operation on the memory, perform a first mutation operation of searching for a next read voltage using a first candidate read voltage when the read operation fails, and perform a second mutation operation of searching for the next read voltage using a second candidate read voltage when the read operation succeeds. The first candidate read voltage may be obtained by applying a first offset value to a default read voltage, and the second candidate read voltage may be obtained by applying a second offset value to the default read voltage.

In an embodiment, a method for operating a storage device may include: performing a first read operation using a default read voltage; searching for a next read voltage, when the first read operation fails, while performing a second read operation using a first candidate read voltage, the first candidate read voltage being obtained by applying a first offset value to the default read voltage; and searching for the next read voltage, when the first read operation succeeds, while performing a third read operation using a second candidate read voltage, the second candidate read voltage being obtained by applying a second offset value to the default read voltage.

In an embodiment, a controller may include: a read operation control unit configured to control a first read operation using a default read voltage; and a next read voltage search unit configured to perform, when the first read operation fails, a second read operation using a first candidate read voltage to search for a next read voltage, the first candidate read voltage being obtained by applying a first offset value to the default read voltage, and perform, when the first read operation succeeds, a third read operation using a second candidate read voltage to search for the next read voltage, the second candidate read voltage being obtained by applying a second offset value to the default read voltage, the second value being smaller than the first offset value.

According to the embodiments of the present disclosure, since an optimal read voltage is searched for and adopted as a next read voltage, in advance, for each of cases where a read operation for a memory included in a storage device fails and succeeds, it is possible to increase the success probability of a read operation for the memory and improve the operational performance of the storage device.

### BRIEF DESCRIPTION OF THE DRAWINGS

FIG. 1 is a diagram illustrating a schematic configuration of a storage device according to an embodiment of the present disclosure.

FIG. 2 is a diagram illustrating a configuration of a memory included in a storage device, according to an embodiment of the present disclosure.

FIG. 3 is a diagram illustrating a configuration of a controller included in a storage device, according to an embodiment of the present disclosure.

FIG. 4 is a diagram illustrating a process in which a storage device performs a mutation operation for adopting a next read voltage, according to an embodiment of the present disclosure.

FIGS. 5, 6, and 7 are diagrams illustrating a scheme in which a storage device performs a first mutation operation, according to an embodiment of the present disclosure.

FIGS. 8, 9, and 10 are diagrams illustrating a scheme in which a storage device performs a second mutation operation, according to an embodiment of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein may be omitted for the interest of brevity. The terms such as “including,” “having,” “containing,” “constituting,” “make up of,” and “formed of” used herein are generally intended to allow other components to be added unless the terms are used with the term “only.” As used herein, singular forms are intended to include plural forms unless the context clearly indicates otherwise. Specifically, the term “a” or “an” entity refers to one or more of that entity. For example, the term “a” or “an,” “one or more,” and “at least one” can be used interchangeably herein. Moreover, a list of items prefaced by a phrase such as “at least one of” or “one or more of” or “one or both of” indicates an inclusive list. For example, a list of “at least one of A and B” and a list of “one or both of A and B” each indicate A, or B, or AB (i.e., A and B).

Terms, such as “first”, “second”, “A,” “B,” “(A),” or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to,” or “contacts or overlaps” a second element, it should be interpreted that, not only can the first element “be directly connected or coupled to” or “directly contact or overlap” the second element, but also can a third element be “interposed” between the first and second elements, or the first and second elements can “be connected or coupled to”or “contact or overlap”each other via a fourth element.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly”or “immediately”is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses the meanings of the term “can.”

Hereinafter, various embodiments of the present disclosure will be described in detail with reference to accompanying drawings.

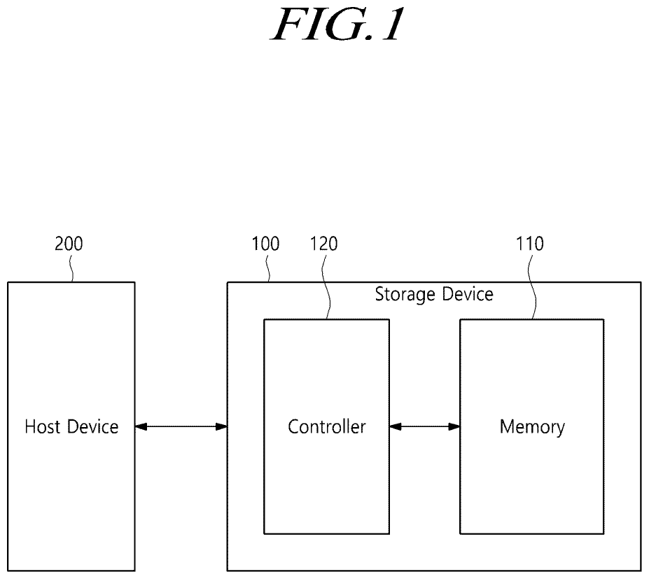

FIG. 1 is a diagram illustrating a schematic configuration of a storage device 100 according to an embodiment of the present disclosure.

Referring to FIG. 1, the storage device 100 may include at least one memory 110. The storage device 100 may include a controller 120 which controls the operation of the memory 110.

The memory 110 may be, for example, volatile memory such as DRAM, SDRAM, DDR SDRAM, and LPDDR SDRAM, but embodiments of the present disclosure are not limited thereto. The memory 110 may be nonvolatile memory such as NAND flash memory, 3D NAND flash memory, and NOR flash memory. As the case may be, one part of the memory 110 included in the storage device 100 may be volatile memory, and the other part may be nonvolatile memory.

In addition, the memory 110 may be one of various types of memory such as resistive RAM, phase change memory, magnetoresistive memory, ferroelectric memory, and spin transfer torque memory. As the case may be, the memory 110 may be processing-in-memory which includes a calculation function or a data processing function.

The memory 110 may include a plurality of storage blocks. Each of the plurality of storage blocks may include a plurality of memory cells. Two or more memory cells may constitute a single page, and a plurality of pages may constitute a single storage block.

The controller 120 may receive a command from the outside, and may control the operation of the memory 110 on the basis of the received command. In addition, the controller 120 may control the operation of the memory 110 on the basis of an internally generated command. In the present disclosure, a command which the controller 120 receives from the outside may be referred to as an external command, and a command which is generated inside the controller 120 may be referred to as an internal command.

The controller 120 may control the operation of the memory 110 on the basis of the external command or the internal command. For example, the controller 120 may control an operation of writing data to the memory 110. The controller 120 may control an operation of reading data written to the memory 110. Data may be transmitted and received between the controller 120 and the memory 110.

Depending on the type of the memory 110, the controller 120 may control a data preservation operation (e.g., a refresh operation or a patrol scrub operation) or an erase operation on data written to the memory 110.

In order to maintain and improve the operational performance of the storage device 100, the controller 120 may perform a background operation associated with the memory 110 on the basis of an external command received from an external host device 200 or on the basis of an internal command. The background operation may include, for example, at least one among garbage collection, wear leveling, read reclaim, and bad block management operations. Through control of the background operation, the controller 120 may improve the operational performance of the storage device 100 or prevent the operational performance of the storage device 100 from deteriorating.

The controller 120 may control the operation of the memory 110 on the basis of a command received from the host device 200. The controller 120 may provide the host device 200 with a processing result according to the operation corresponding to the command. The controller 120 may transmit data or a response signal to the host device 200.

For example, the host device 200 may be a computer, an ultra mobile PC (UMPC), a workstation, a personal digital assistant (PDA), a tablet, a mobile phone, a smartphone, an e-book, a portable multimedia player (PMP), a portable game player, a navigation device, a black box, a digital camera, a digital multimedia broadcasting (DMB) player, a smart television, a digital audio recorder, a digital audio player, a digital picture recorder, a digital picture player, a digital video recorder, a digital video player, a storage configuring a data center, one of various electronic devices configuring a home network, one of various electronic devices configuring a telematics network, an RFID (radio frequency identification) device, a mobility device (e.g., a vehicle, a robot or a drone) capable of traveling under human control or autonomous driving, or the like. Alternatively, the host device 200 may be a virtual/augmented reality device which provides a 2D or 3D virtual reality image or augmented reality image. Besides, the host device 200 may be any one of various electronic devices, each of which requires the storage device 100 capable of storing data.

The host device 200 may include at least one operating system. The operating system may manage and control overall functions and operations of the host device 200, and may control an interoperation between the host device 200 and the storage device 100. The operating system may be classified into a general operating system and a mobile operating system depending on the mobility of the host device 200.

The controller 120 and the host device 200 may be devices which are separated from each other. As the case may be, the controller 120 and the host device 200 may be implemented by being integrated as a single device, or some components or functions of the controller 120 may be implemented by being included in the host device 200. Hereunder, for the sake of convenience in explanation, it will be described as an example that the controller 120 and the host device 200 are devices which are separated from each other.

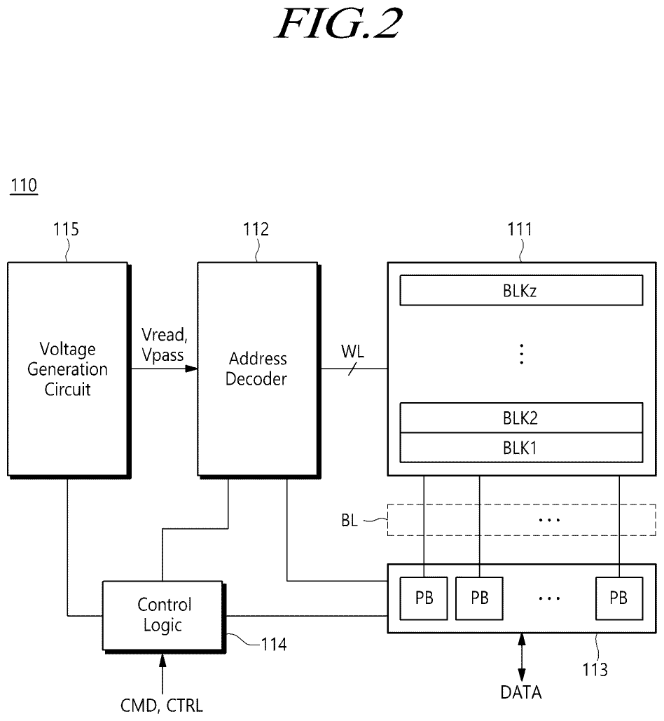

FIG. 2 is a diagram illustrating a configuration of a memory (e.g., the memory 110 included in the storage device 100 in FIG. 1) according to an embodiment of the present disclosure.

Referring to FIG. 2, the memory 110 may include a memory cell array 111, an address decoder 112, a read and write circuit 113, a control logic 114, and a voltage generation circuit 115.

The memory cell array 111 may include a plurality of storage blocks BLK1 to BLKz (z is a natural number of 2 or more).

In the plurality of storage blocks BLK1 to BLKz, a plurality of word lines WL and a plurality of bit lines BL may be disposed, and a plurality of memory cells may be arranged.

The plurality of storage blocks BLK1 to BLKz may be connected to the address decoder 112 through the plurality of word lines WL. The plurality of storage blocks BLK1 to BLKz may be connected to the read and write circuit 113 through the plurality of bit lines BL.

Each of the plurality of storage blocks BLK1 to BLKz may include a plurality of memory cells. The plurality of memory cells are nonvolatile memory cells, and may be configured with nonvolatile memory cells which have a vertical channel structure.

The memory cell array 111 may be configured as a memory cell array with a two-dimensional structure, and as the case may be, may be configured as a memory cell array with a three-dimensional structure.

Each of the plurality of memory cells included in the memory cell array 111 may store at least 1 bit of data. For example, each of the plurality of memory cells included in the memory cell array 111 may be a single-level cell (SLC) which stores 1 bit of data. For another example, each of the plurality of memory cells included in the memory cell array 111 may be a multi-level cell (MLC) which stores 2 bits of data, a triple-level cell (TLC) which stores 3 bits of data, a quad-level cell (QLC) which stores 4 bits of data, or a memory cell which stores at least 5 bits of data.

The number of bits of data stored in each of the plurality of memory cells may be dynamically determined. For example, a single-level cell which stores 1 bit of data may be changed to a triple-level cell which stores 3 bits of data.

The address decoder 112, the read and write circuit 113, the control logic 114 and the voltage generation circuit 115 may operate as a peripheral circuit which drives the memory cell array 111.

The address decoder 112 may be connected to the memory cell array 111 through the plurality of word lines WL. The address decoder 112 may be configured to operate in response to control of the control logic 114.

The address decoder 112 may receive an address through an input/output buffer in the memory 110. The address decoder 112 may be configured to decode a block address in the received address. The address decoder 112 may select at least one storage block BLK according to the decoded block address.

The address decoder 112 may receive a read voltage Vread and a pass voltage Vpass from the voltage generation circuit 115.

In an operation of applying the read voltage Vread during a read operation, the address decoder 112 may apply the read voltage Vread to a selected word line WL in a selected storage block BLK, and may apply the pass voltage Vpass to remaining unselected word lines WL.

In a program verify operation, the address decoder 112 may apply a verify voltage generated in the voltage generation circuit 115 to a selected word line WL in a selected storage block BLK, and may apply the pass voltage Vpass to remaining unselected word lines WL.

The address decoder 112 may be configured to decode a column address in the received address. The address decoder 112 may transmit the decoded column address to the read and write circuit 113.

A read operation and a program operation of the memory 110 may be performed in the unit of page. An address received when each of the read operation and the program operation is requested may include at least one of a block address, a row address, and a column address.

The address decoder 112 may select a single storage block BLK and a single word line WL according to the block address and the row address. The column address may be decoded by the address decoder 112, and the decoded column address may be provided to the read and write circuit 113.

The address decoder 112 may include at least one of a block decoder, a row decoder, a column decoder, and an address buffer.

The read and write circuit 113 may include a plurality of page buffers PB. The read and write circuit 113 may operate as a read circuit in a read operation of the memory cell array 111, and may operate as a write circuit in a write operation of the memory cell array 111.

The read and write circuit 113 may also be referred to as a page buffer circuit or a data register circuit which includes the plurality of page buffers PB. The read and write circuit 113 may include a data buffer which takes charge of a data processing function, and as the case may be, may additionally include a cache buffer which takes charge of a caching function.

The plurality of page buffers PB may be connected to the memory cell array 111 through the plurality of bit lines BL. In order to sense threshold voltages (Vth) of memory cells in a read operation and a program verify operation, the plurality of page buffers PB may continuously supply sensing current to bit lines BL connected to the memory cells, and may latch sensing data by sensing, through sensing nodes, that amounts of current flowing according to programmed states of the corresponding memory cells change.

The read and write circuit 113 may operate in response to page buffer control signals outputted from the control logic 114.

In a read operation, the read and write circuit 113 may temporarily store read data by sensing data of memory cells, and then, may output data DATA to the input/output buffer of the memory 110. As an example, the read and write circuit 113 may include a column select circuit and so on in addition to the page buffers PB or page registers.

The control logic 114 may be connected to the address decoder 112, the read and write circuit 113, and the voltage generation circuit 115. The control logic 114 may receive a command CMD and a control signal CTRL through the input/output buffer of the memory 110.

The control logic 114 may be configured to control overall operations of the memory 110 in response to the control signal CTRL. The control logic 114 may output a control signal for adjusting the precharge potential level of the sensing nodes of the plurality of page buffers PB.

The control logic 114 may control the read and write circuit 113 to perform a read operation of the memory cell array 111. The voltage generation circuit 115 may generate the read voltage Vread and the pass voltage Vpass used in the read operation, in response to a voltage generation circuit control signal outputted from the control logic 114.

Each of the storage blocks BLK of the memory 110 described above may be composed of a plurality of pages corresponding to a plurality of word lines WL and a plurality of strings corresponding to a plurality of bit lines BL.

In a storage block BLK, a plurality of word lines WL and a plurality of bit lines BL may be disposed to intersect each other. A memory cell which is connected to one of the plurality of word lines WL and one of the plurality of bit lines BL may be defined. A transistor may be disposed in each memory cell.

The transistor disposed in the memory cell may include a drain, a source, and a gate. The drain (or source) of the transistor may be connected to a corresponding bit line BL directly or via another transistor. The source (or drain) of the transistor may be connected to a source line (which may be the ground) directly or via another transistor. The gate of the transistor may include a floating gate which is surrounded by a dielectric and a control gate to which a gate voltage is applied from a word line WL.

In each storage block BLK, a first select line (also referred to as a source select line or a drain select line) may be additionally disposed outside a first outermost word line WL more adjacent to the read and write circuit 113 between two outermost word lines WL, and a second select line (also referred to as a drain select line or a source select line) may be additionally disposed outside a second outermost word line WL between the two outermost word lines WL.

As the case may be, at least one dummy word line may be additionally disposed between the first outermost word line and the first select line. At least one dummy word line may also be additionally disposed between the second outermost word line and the second select line.

A read operation and a program operation (write operation) of the storage block BLK described above may be performed in the unit of page, and an erase operation may be performed in the unit of storage block BLK of the memory 110.

As a program operation, a read operation, or an erase operation on a memory cell is repeated, degradation of the memory cell may progress. Due to the degradation of the memory cell, the threshold voltage of a transistor included in the memory cell may change. Due to the change in the threshold voltage, a read operation by an existing read voltage may fail.

Embodiments of the present disclosure may increase the success probability of a read operation and improve the operational performance of the storage device 100 by easily searching for an optimal read voltage or searching for the optimal read voltage in advance.

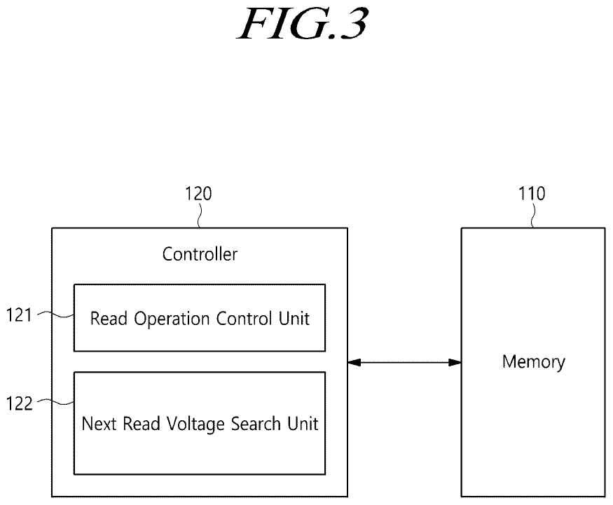

FIG. 3 is a diagram illustrating a configuration of a controller (e.g., the controller 120 included in the storage device 100 in FIG. 1) according to an embodiment of the present disclosure.

Referring to FIG. 3, the controller 120 of the storage device 100 may include, for example, a read operation control unit 121 and a next read voltage search unit 122. For example, the read operation control unit 121 may be implemented using hardware (e.g., a read operation control circuit), or software, or both. Similarly, the next read voltage search unit 122 may be implemented using hardware (e.g., a next read voltage search circuit), or software, or both.

The read operation control unit 121 may control a read operation on the memory 110 using a previously set read voltage.

The previously set read voltage may be a read voltage which is set as a default value. Alternatively, the previously set read voltage may be a read voltage used when a latest read operation succeeded. The read voltage used when the latest read operation succeeded may also be referred to as a history read voltage or a history bias. In the present specification, the previously set read voltage may be referred to as a default read voltage.

The next read voltage search unit 122 may perform an operation of searching for a next read voltage, depending on whether the read operation according to the read operation control unit 121 succeeds.

The next read voltage may indicate a read voltage which is determined as an optimal read voltage compared to the previously set read voltage according to the degradation of a memory cell included in the memory 110.

The next read voltage search unit 122 may search for the next read voltage when the read operation by the read operation control unit 121 fails. In addition, as the case may be, the next read voltage search unit 122 may search for the next read voltage even when the read operation by the read operation control unit 121 succeeds.

For example, the read operation control unit 121 of the controller 120 may control a first read operation using the default read voltage. A read operation according to the first read operation may fail or succeed.

When the first read operation by the default read voltage fails, the next read voltage search unit 122 may perform a second read operation using at least one first candidate read voltage. The first candidate read voltage may be a voltage which is obtained by applying a first offset value to the default read voltage.

The next read voltage search unit 122 may perform the second read operation by using the first candidate read voltage which is obtained by adding the first offset value to the default read voltage or by subtracting the first offset value from the default read voltage.

On the basis of a candidate error check node value obtained in the second read operation using the first candidate read voltage, the next read voltage search unit 122 may determine whether to adopt the first candidate read voltage as the next read voltage. The candidate error check node value may be a value based on the numbers of fail bits for a plurality of memory cells corresponding to an error check node. For example, the sum of the numbers of fail bits for the plurality of memory cells corresponding to the error check node may be the candidate error check node value. In an embodiment, the candidate error check node value may be a value that is determined on the basis of a fail bit for at least one of a plurality of memory cells that respectively correspond to a plurality of error check nodes.

The next read voltage search unit 122 may obtain an initial value of a default error check node value in the first read operation by the default read voltage. The default error check node value may be a value based on fail bits for the plurality of memory cells corresponding to the error check node in the first read operation. In an embodiment, the default error check node value may be a value that is determined on the basis of a fail bit for at least one of a plurality of memory cells that respectively correspond to a plurality of error check nodes. For example, the first read operation may be performed a plurality of times, and the next read voltage search unit 122 may obtain the initial value of the default error check node value obtained in an initial read operation. The initial value of the default error check node value may be stored in the memory 110 or the controller 120 until the first read operation is completed, and may be provided to the next read voltage search unit 122 after the first read operation is completed.

The next read voltage search unit 122 may check whether the candidate error check node value obtained in the second read operation by the first candidate read voltage is smaller than the initial value of the default error check node value obtained in the first read operation by the default read voltage.

When the candidate error check node value is smaller than the initial value of the default error check node value, the next read voltage search unit 122 may adopt the corresponding first candidate read voltage as the next read voltage. When the candidate error check node value is equal to or greater than the initial value of the default error check node value, the next read voltage search unit 122 may not adopt the corresponding first candidate read voltage as the next read voltage.

When the first candidate read voltage is not adopted as the next read voltage, the next read voltage search unit 122 may perform a second read operation with a new first candidate read voltage by changing the first offset value.

By performing the second read operation by selecting a first candidate read voltage in a direction in which a candidate error check node value decreases, the next read voltage search unit 122 may adopt the next read voltage. For example, the next read voltage search unit 122 may perform the second read operation using a first candidate read voltage which is located opposite to the first candidate read voltage previously selected on the basis of the default read voltage. As a first offset value with an opposite sign is applied to the default read voltage, the new first candidate read voltage may be selected. For example, when the first candidate read voltage previously selected has a first value, the controller 120 including the next read voltage search unit 122 may perform the second read operation using the first candidate read voltage having a second value that is located opposite to the first value with respect to the default read voltage.

The next read voltage search unit 122 may check whether the second read operation by the selected first candidate read voltage succeeds, and when the second read operation succeeds, may adopt the first candidate read voltage used when the second read operation succeeds, as a final next read voltage.

The operation of adopting the final next read voltage through the second read operation may be referred to as a first mutation operation. The next read voltage search unit 122 may adopt the next read voltage by searching for an optimal first candidate read voltage through comparison between a candidate error check node value and the default error check node value. Since the next read voltage is searched for on the basis of error check node values, the next read voltage may be searched for by changing the first candidate read voltage in a direction approaching an optimal read voltage.

As the case may be, even when a read operation by the first read operation succeeds, the next read voltage search unit 122 may perform a third read operation of searching for the next read voltage. An operation of searching for the next read voltage through the third read operation may be referred to as a second mutation operation.

For example, when the number of read operations on a corresponding memory cell or word line WL is equal to or greater than a preset reference value, the next read voltage search unit 122 may perform an operation of searching for the next read voltage even when the first read operation succeeds. Specifically, when the number of read operations on a single wordline WL is equal to or greater than a preset reference value, the controller 120 including the next read voltage search unit 122 may perform the second mutation operation.

Alternatively, when the number of fail bits due to the first read operation is included between a preset lower limit value and a preset upper limit value, the next read voltage search unit 122 may perform an operation of searching for the next read voltage. As the case may be, when the number of read operations is equal to or greater than a preset reference value and the number of fail bits is included within a preset range, the next read voltage search unit 122 may perform the second mutation operation of searching for the next read voltage.

The next read voltage search unit 122 may perform the third read operation using at least one second candidate read voltage. The second candidate read voltage may be a read voltage which is obtained by applying a second offset value to the default read voltage. The second offset value may be different from the first offset value. For example, the second offset value may be a value smaller than the first offset value.

The next read voltage search unit 122 may perform the third read operation using the second candidate read voltage which is obtained as the second offset value smaller than the first offset value is applied.

Since it is a state in which a read operation by the first read operation succeeds, the third read operation may be a read operation that is subsequently performed on the same memory cell or the same word line WL after the first read operation succeeds. In a read operation that is performed next by the next read voltage search unit 122 after a read operation succeeds, the read operation using the second candidate read voltage which is obtained by applying the second offset value is performed, and an operation of searching for an optimal read voltage may be performed.

The next read voltage search unit 122 may compare the number of fail bits obtained in the third read operation by the second candidate read voltage with the number of fail bits obtained in the first read operation by the default read voltage. On the basis of whether the number of fail bits obtained in the third read operation decreases, the next read voltage search unit 122 may determine whether to adopt the second candidate read voltage as the next read voltage.

Alternatively, on the basis of whether the difference between the number of fail bits obtained in the third read operation by the second candidate read voltage and the number of fail bits obtained in the first read operation by the default read voltage is equal to or greater than a preset threshold, the next read voltage search unit 122 may determine whether to adopt the second candidate read voltage as the next read voltage.

The next read voltage search unit 122 may adopt the corresponding second candidate read voltage as the next read voltage even when only the number of fail bits obtained in the third read operation by the second candidate read voltage decreases, or may adopt the corresponding second candidate read voltage as the next read voltage only when the number of fail bits that decreases is equal or higher than a predetermined level.

The next read voltage search unit 122 may stop the second mutation operation when the third read operation by the second candidate read voltage fails. When the second mutation operation is stopped by the next read voltage search unit 122, the read operation control unit 121 may control a subsequent read operation by the default read voltage.

In embodiments of the present disclosure, in the case where when a read operation by a default read voltage fails, a direction of searching for a first candidate read voltage is determined on the basis of whether a candidate error check node value obtained in a read operation by the first candidate read voltage decreases. Therefore, searching for a next read voltage may be easily performed.

In addition, even in the case where a read operation by a default read voltage succeeds, a next read voltage is searched for on the basis of the number of fail bits obtained in a read operation by a second candidate read voltage. Therefore, an optimal read voltage may be searched for in advance, and control may be performed so that an efficient read operation is performed.

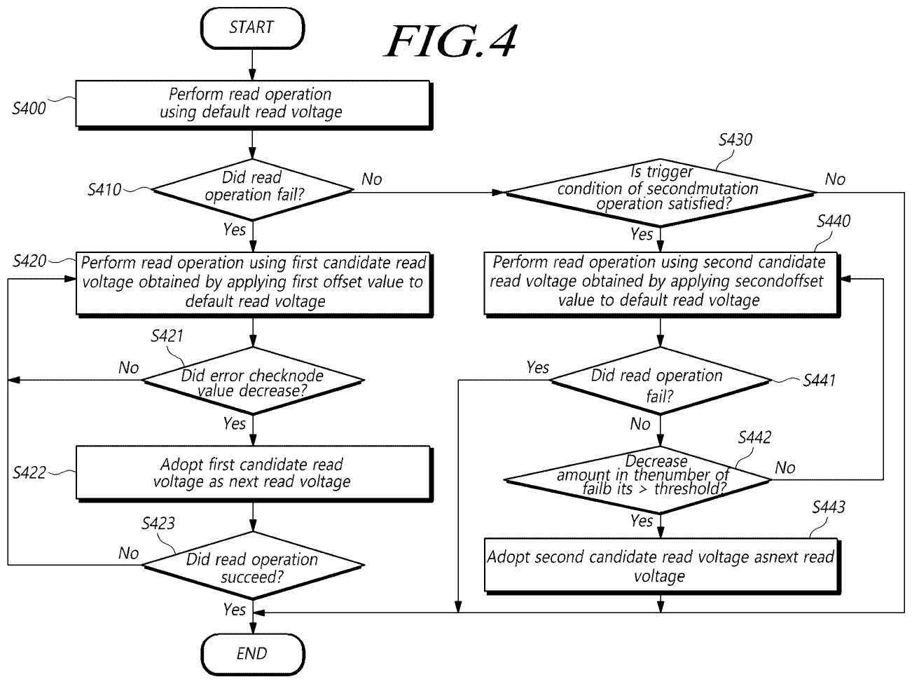

FIG. 4 is a diagram illustrating an example of a process in which a storage device (e.g., the storage device 100 in FIG. 1) according to an embodiment of the present disclosure performs a mutation operation for adopting a next read voltage.

Referring to FIG. 4, the controller 120 of the storage device 100 may perform a read operation using a default read voltage when performing a read operation according to a read command (S400).

When the read operation by the default read voltage fails (S410), the controller 120 may perform a read operation using a first candidate read voltage which is obtained by applying a first offset value to the default read voltage (S420).

The controller 120 may check whether an error check node value obtained in the read operation using the first candidate read voltage decreases (S421).

When the error check node value obtained in the read operation by the first candidate read voltage decreases compared to (or is smaller than) an initial value of an error check node value obtained in the read operation by the default read voltage, the controller 120 may adopt the first candidate read voltage as a next read voltage (S422). The controller 120 may check whether the read operation by the first candidate read voltage succeeds (S423), and when the read operation succeeds, may end the read operation by the first candidate read voltage. The controller 120 may end a first mutation operation by the first candidate read voltage, and may set the adopted next read voltage as a final optimal next read voltage. In a subsequent read operation, the controller 120 may perform the read operation using the final optimal next read voltage.

When the read operation by the default read voltage succeeds, the controller 120 may check whether a trigger condition of a second mutation operation is satisfied (S430).

The second mutation operation may be triggered on the basis of, for example, the number of read operations on a corresponding memory cell or word line WL and the number of fail bits by a corresponding read operation.

Even in the case where the read operation by the default read voltage succeeds, when the trigger condition of the second mutation operation is satisfied, the controller 120 may perform, in a subsequent read operation, a read operation using a second candidate read voltage which is obtained by applying a second offset value to the default read voltage (S440).

When the read operation by the second candidate read voltage fails (S441), the controller 120 may stop the second mutation operation, and may perform a read operation using the previously set default read voltage.

When the read operation by the second candidate read voltage succeeds, the controller 120 may check whether a decrease in the number of fail bits is greater than a threshold (S442).

For example, when an amount by which the number of fail bits obtained in the read operation using the second candidate read voltage decreases compared to the number of fail bits obtained in read operation using the default read voltage is greater than the preset threshold, the controller 120 may adopt the second candidate read voltage as the next read voltage (S443).

When the next read voltage is adopted, the controller 120 may stop the second mutation operation. As the case may be, the controller 120 may search for an optimal next read voltage by continuously performing the second mutation operation. In this case, when a read operation by a second candidate read voltage fails, the controller 120 may perform a subsequent read operation using a latest next read voltage adopted as a default read voltage.

Embodiments of the present disclosure may provide measures for efficiently searching for an optimal next read voltage by a mutation operation of searching for a next read voltage when a read operation succeeds or fails. Also, since whether to adopt a next read voltage is determined on the basis of an error check node value or the number of fail bits, an optimal next read voltage may be easily searched for.

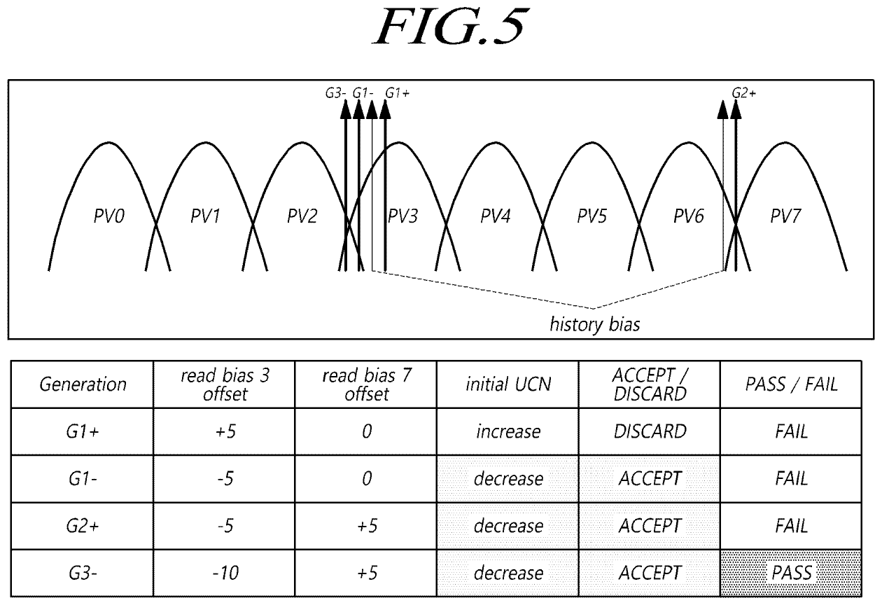

FIGS. 5 to 7 are diagrams illustrating a scheme in which a storage device (e.g., the storage device 100 in FIG. 1) performs a first mutation operation, according to an embodiment.

Referring to FIG. 5, an example is shown in which a read operation is performed when a memory cell included in the memory 110 of the storage device 100 is a triple-level cell which stores 3 bits of data.

When a memory cell operates as a triple-level cell, read operations may be performed on, for example, a least significant bit, a most significant bit, and a central significant bit. FIG. 5 illustrates a case where a read operation is performed using a third read bias and a seventh read bias to read a least significant bit.

The controller 120 may perform an operation of reading the least significant bit using a history bias corresponding to a default read voltage. When the read operation using the default read voltage fails, the controller 120 may obtain an initial value of an error check node value according to the corresponding read operation. The initial value of the error check node may indicate an error level when the read operation using the default read voltage fails. For example, the error check node value may an unsatisfied check node (UCN), and the initial value may be a value first obtained among error check node values according to the read operation.

According to the failure of the read operation, the controller 120 may perform a first mutation operation for searching for a next read voltage.

In order to search for a next read voltage for the third read bias, the controller 120 may perform a read operation using a first candidate read voltage which is obtained as a first offset value is applied to the default read voltage. The first offset value may be, for example, +5, and the controller 120 may perform a read operation using the first candidate read voltage which is obtained by applying (e.g., adding) +5 to the default read voltage.

The controller 120 may check an error check node value which is obtained in the read operation by the first candidate read voltage obtained by applying the first offset value of +5 to the default read voltage. When the error check node value obtained in the read operation by the first candidate read voltage increases compared to the initial value of the error check node value by the default read voltage, the controller 120 may not adopt the first candidate read voltage as a next read voltage and may discard the first candidate read voltage.

The controller 120 may perform a read operation by changing the first offset value to −5. The controller 120 may perform a read operation using a first candidate read voltage which is obtained as a first offset value corresponding to −5 is applied to the default read voltage.

The controller 120 may check an error check node value which is obtained in the read operation by the first candidate read voltage obtained by applying the first offset value of −5 to the default read voltage. When the error check node value obtained in the read operation by the first candidate read voltage decreases compared to the initial value of the error check node value obtained in the read operation by the default read voltage, the controller 120 may adopt the first candidate read voltage as a next read voltage.

When the read operation by the adopted next read voltage fails, the controller 120 may continuously perform the first mutation operation by applying a new first offset value.

For example, the controller 120 may perform a read operation using a first candidate read voltage which is obtained as a first offset value corresponding to +5 is applied to the seventh read bias in a state in which a first offset value for the third read bias is set to −5.

When an error check node value obtained in the read operation by the first candidate read voltage decreases, the controller 120 may adopt the corresponding first candidate read voltage as a next read voltage. Because the read operation has failed, the controller 120 may perform a read operation using a new first candidate read voltage.

For example, the controller 120 may perform a read operation using a first candidate read voltage which is obtained as a first offset value corresponding to −10 is applied to the third read bias. Because the error check node value has decreased when the first offset value of −5 is applied to the third read bias, the first candidate read voltage may be selected by applying the first offset value increased in a corresponding direction.

The controller 120 may perform the read operation by applying the first offset value of −10 to the default read voltage for the third read bias and by applying the first offset value of +5 to the default read voltage for the seventh read bias.

Because an error check node value decreases, the controller 120 may adopt the corresponding first candidate read voltage as a next read voltage. Since the read operation has succeeded, the controller 120 may determine the adopted next read voltage as a final optimal next read voltage and end the first mutation operation.

As described above with reference to FIG. 5, the first offset value may be at least one first offset value (e.g., a plurality of first offset values), and the first candidate read voltage may be at least one first candidate read voltage (e.g., a plurality of first candidate read voltages). For example, referring to generation G1+ of FIG. 5, the controller 120 performs a read operation using a first one of the first candidate read voltages obtained by applying a first one (+5) of the first offset values of to a default read voltage for the third read bias. Referring to generation G1− of FIG. 5, the controller 120 changes the first one of the first offset values to a different value (−5), obtains the first one of the first candidate read voltages by applying the changed first one (−5) of the first offset values to the default read voltage, performs a read operation using the first one of the first candidate read voltages, and adopts the first one of the first candidate read voltages as a next read voltage for the third read bias. Referring to generation G2+ of FIG. 5, the controller 120 obtains a second one of the first candidate read voltages by applying a second one (e.g., +5) of the first offset values to a default read voltage for the seventh read bias, performs a read operation using the second one of the first candidate read voltages, and adopts the second one of the first candidate read voltages as a next read voltage for the seventh bias. Referring to generation G3−, the controller 120 changes the first one of the first offset values to a different value (−10), obtains the first one of the first candidate read voltages by applying the changed first one (−10) of the first offset values to the default read voltage for the third read bias, and performs a read operation using the first one of the first candidate read voltages, and adopts the first one of the first candidate read voltages as a next read voltage for the third read bias.

In the embodiment of FIG. 5, each of the first one and the second one of first candidate read voltages is adopted as a next read voltage when a corresponding error check node value is less than the initial value of the default error check node value, but embodiments of the present disclosure are not limited thereto. For example, each of the first one and the second one of first candidate read voltages may be adopted as a next read voltage when an error check node value (e.g., the error check node value in generation G2+) is less than an immediately preceding error check node value (e.g., the error check node value in generation G1−).

Since the controller 120 selects a first offset value and a first candidate read voltage on the basis of a change in error check node value, searching for a next read voltage may be facilitated. By determining a final next read voltage according to whether a read operation fails or succeeds, the controller 120 may search for an optimal next read voltage.

As the case may be, the controller 120 may search for a next read voltage while changing a first offset value according to progress of the first mutation operation.

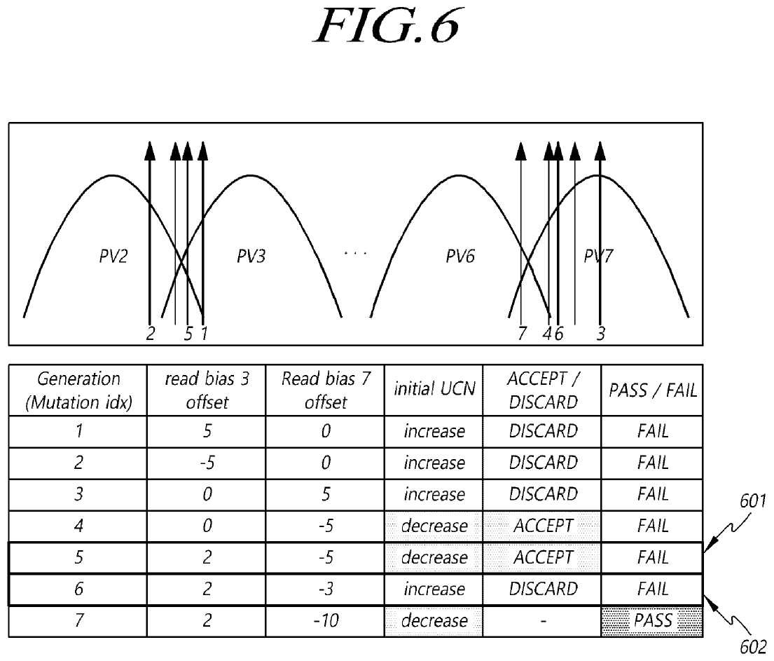

For example, referring to FIG. 6, the controller 120 may perform the first mutation operation of searching for an optimal next read voltage with respect to a third read bias and a seventh read bias.

Similarly to the example illustrated in FIG. 5, in order to search for the third read bias, the controller 120 may perform read operations using first candidate read voltages which are obtained as a first offset value of +5 and a first offset value of −5 are applied to a default read voltage.

Because error check node values obtained in the corresponding read operations increase compared to the initial value of the error check node value obtained in the initial read operation, the controller 120 may not adopt and discard the corresponding first candidate read voltages.

Since searching for the third read bias has failed, the controller 120 may perform read operations using first candidate read voltages which are obtained by changing a first offset value for the third read bias to 0 and applying a first offset value of +5 and a first offset value of −5 to the default read voltage to search for the seventh read bias.

Because an error check node value increases when the first offset value of +5 is applied to the seventh read bias, the controller 120 may discard the corresponding first candidate read voltage. Because an error check node value decreases when the first offset value of −5 is applied to the seventh read bias, the controller 120 may adopt the corresponding first candidate read voltage as a next read voltage.

Because the read operation fails, the controller 120 may perform a read operation using a new first candidate read voltage which is obtained by applying a new first offset value.

The controller 120 may apply a new first offset value to the third read bias. Because the error check node values have increased in both cases where the first offset value of +5 and the first offset value of −5 were previously applied to the third read bias, the controller 120 may select a first candidate read voltage by changing the first offset value.

For example, as indicated by 601 in FIG. 5, the controller 120 may select a first candidate read voltage by applying a first offset value of +2 to the third read bias. By applying a first offset value that is reduced from the absolute value of the previous first offset value of +5 or −5, the controller 120 may select a first candidate read voltage. The controller 120 may apply the previously adopted first offset value of −5 to the seventh read bias.

Because an error check node value according to a read operation decreases, the controller 120 may adopt the corresponding first candidate read voltage as a next read voltage. Because the read operation fails, the controller 120 may perform a read operation by a new first candidate read voltage.

The controller 120 may change the first offset value for the seventh read bias, and as indicated by 602 in FIG. 6, may perform a read operation by changing the first offset value for the seventh read bias from −5 to −3. Because an error check node value according to the read operation increases, the controller 120 may discard the corresponding first candidate read voltage. The controller 120 may select a first offset value for the seventh read bias by changing the first offset value in an opposite direction, and since the first offset value of −5 were changed to the first offset value of −3, −10 that is located in an opposite direction may be selected as a first offset value.

The controller 120 may perform a read operation using a first candidate read voltage which is obtained as the first offset value of +2 is applied to the third read bias and the first offset value of −10 is applied to the seventh read bias.

Because an error check node value decreases, the controller 120 may adopt the corresponding first candidate read voltage as a next read voltage. Since the read operation succeeds, the controller 120 may set the adopted next read voltage as a final optimal next read voltage, and may end the first mutation operation.

In this way, depending on whether an error check node value increases or decreases, the controller 120 may perform an operation of searching for a next read voltage while changing a first offset value.

In addition, as the case may be, even in a case where an error check node value is not provided, the controller 120 may search for a next read voltage while applying a first offset value according to an embodiment of the present disclosure.

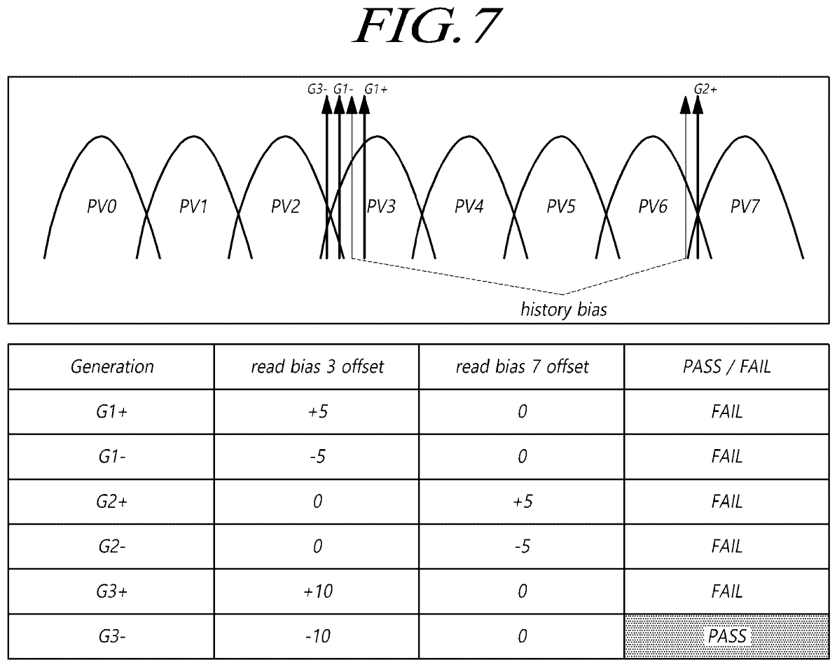

For example, referring to FIG. 7, since it is a case where an error check node value is not obtained in a read operation by a first candidate read voltage, the controller 120 may search for a next read voltage on the basis of whether the read operation by the first candidate read voltage succeeds.

Even in this case, the controller 120 may select a first candidate read voltage while setting a first offset value similarly to the examples described above.

The controller 120 may perform a read operation by applying a first offset value of +5 to a third read bias, and, in case of a fail, may perform a read operation by applying a first offset value of −5.

Because both the read operations performed by applying the first offset values to the third read bias fail, the controller 120 may perform read operations by maintaining the first offset value for the third read bias as 0 and applying first offset values of +5 and −5 to a seventh read bias.

Because both the read operations performed by applying the first offset values of +5 and −5 to the seventh read bias fail, the controller 120 may perform read operations using first candidate read voltages which are obtained by maintaining a first offset value for the seventh read bias as 0 and applying to the third read bias a first offset value of +10 and a first offset value of −10 whose absolute values are increased compared to the previous first offset values.

Because the read operation succeeds when the first offset value of −10 is applied to the third read bias and the first offset value of 0 is applied to the seventh read bias (i.e., the seventh read bias is a default read voltage or a history read voltage), the controller 120 may adopt the corresponding first candidate read voltage as a final optimal next read voltage, and may end the first mutation operation.

In this way, even when not using an error check node value, the controller 120 may perform an operation of searching for a next read voltage while changing a first offset value. The controller 120 may perform a searching operation for a next read voltage by applying at least one first offset value to at least one read voltage used when a latest read operation succeeded, thereby making the searching operation more efficient than a conventional searching operation. Without separately storing candidates or a table for read voltages to be used when a read operation by a default read voltage fails, the controller 120 may determine an optimal next read voltage through a search using a first candidate read voltage, and may perform a read operation.

Even when a read operation by a default read voltage succeeds, the controller 120 may search for an optimal next read voltage in advance through a second mutation operation.

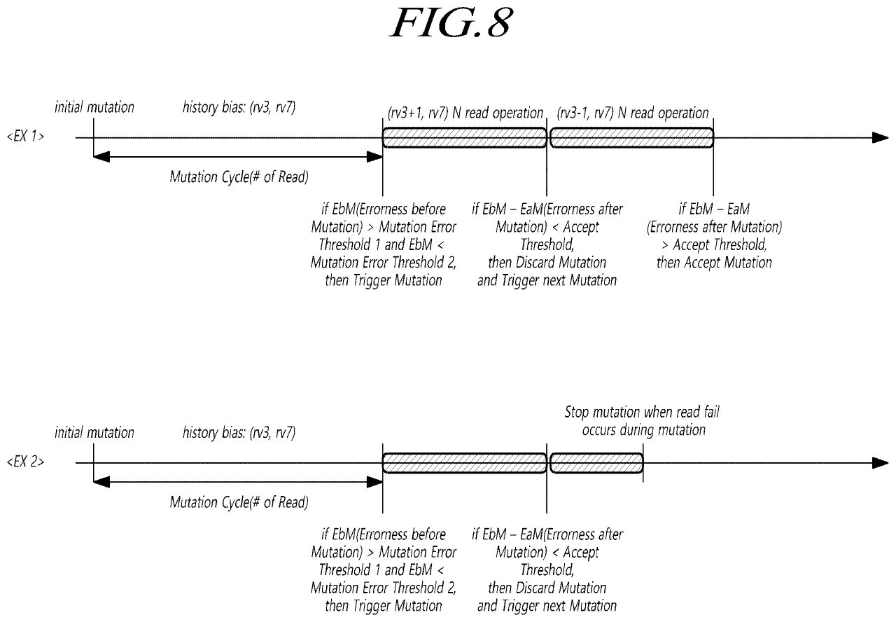

FIGS. 8 to 10 are diagrams illustrating an example of a scheme in which a storage device (e.g., the storage device 100 in FIG. 1) according to embodiments of the present disclosure performs a second mutation operation.

Referring to FIG. 8, when a read operation by a default read voltage succeeds, the controller 120 may perform the second mutation operation for searching for a next read voltage (e.g., an optimal next read operation).

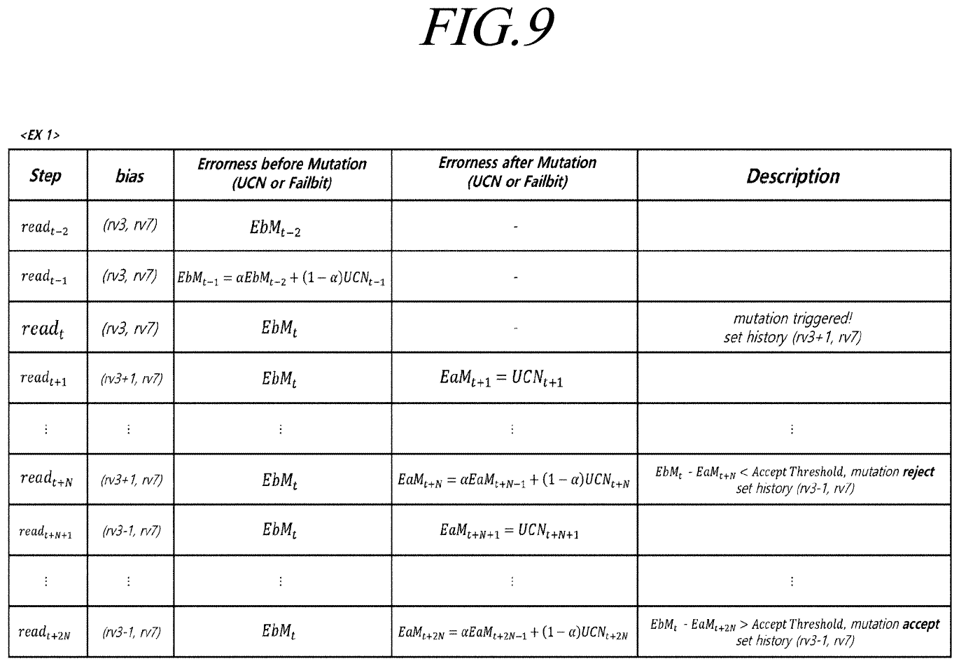

Referring to <EX1> of FIG. 8 and FIG. 9, for example, when the number of read operations on a corresponding memory cell or word line WL is equal to or greater than a preset reference value, the controller 120 may determine whether to perform the second mutation operation. As the case may be, the number of read operations may include the number of program operations or erase operations.

In a state in which the number of read operations is equal to or greater than the preset reference value, the controller 120 may check whether error quantity (e.g,. the number of fail bits), which is indicated by “Errorness” in FIGS. 8-10 and obtained according to a corresponding read operation, is greater than (or equal to or greater than) a preset lower limit value and smaller than (or equal to or smaller than) a preset upper limit value. When the number of fail bits obtained when the read operation succeeds is within the preset range, the controller 120 may determine to perform the second mutation operation.

When the number of fail bits obtained by the read operation is smaller than the preset lower limit value, a search for a next read voltage may not be required. When the number of fail bits obtained by the read operation is greater than the preset upper limit value, the probability that a read operation by searching for a next read voltage will fail may increase. By performing the second mutation operation only when the number of fail bits obtained by the read operation is within the preset range, the controller 120 may effectively perform a search for a next read voltage, according to the second mutation operation.

For example, in an example illustrated in FIG. 9, because the numbers of fail bits obtained in read operations performed at times t-2 and t-1 do not satisfy the trigger condition of the second mutation operation, the controller 120 may not perform the second mutation operation. Because the number of fail bits obtained in a read operation performed at a time t satisfies the trigger condition of the second mutation operation, the controller 120 may perform the second mutation operation.

While performing a read operation, the controller 120 may use a second candidate read voltage which is obtained by applying a second offset value. The read operation by the second candidate read voltage may be a read operation according to a new read command. When performing a new read operation after a read operation succeeds, the controller 120 may perform the second mutation operation in which a next read voltage is searched for while performing the read operation using a second candidate read voltage which is changed from the default read voltage.

The controller 120 may obtain the number of fail bits while performing the read operation N (N is an integer satisfying N≥2) times using the second candidate read voltage. N may indicate a period or a number of times set according to a period for determining, when performing a mutation operation, whether a next read voltage derived according to the mutation operation is valid.

The controller 120 may store the numbers of fail bits the N times and calculate an average value. Alternatively, in order to reduce unnecessary use of a storage space, the controller 120 may obtain an average value of the numbers of fail bits by calculating a sum by applying a weight to each of the obtained number of fail bits and the previous number of fail bits. The average value may be a moving average value for tracking the numbers of fail bits that change during the N read operations (or a read operation performed N times). The controller 120 may obtain a moving average value of the numbers of fail bits by applying preset weights.

For example, by applying a weight (1-α) to the error quantity (e.g., the number of fail bits or an error check node value) UCN_{t+N} obtained at a time t+N illustrated in FIG. 9 and by applying a weight α to the previously obtained number of fail bits EaM_{t+N-1}, the number of fail bits EaM_{t+N} may be calculated. (1-α) and α may be weights that are multiplied to the current number of fail bits and the previously calculated number of fail bits, respectively. α may be a preset value and may be a fixed value. Among the numbers of fail bits that change while the N read operations are performed, the controller 120 may apply a greater weight to the previously obtained number of fail bits or may apply a greater weight to the finally obtained number of fail bits. The controller 120 may set the value of α according to a moving average value to track, and may calculate the average value of the numbers of fail bits while the N read operations are performed.

The controller 120 may compare the average value of the numbers of fail bits through the N times with the number of fail bits obtained in a read operation by a default read voltage before the second mutation operation is triggered.

When the difference between the average value of the numbers of fail bits according to the N read operations in the second mutation operation and the number of fail bits obtained in the read operation by the default read voltage is less than a preset threshold, the controller 120 may not adopt the corresponding second candidate read voltage as a next read voltage.

The controller 120 may perform a new second mutation operation while changing the second offset value. The controller 120 may perform a read operation using a second candidate read voltage which is obtained as a changed second offset value is applied, and may calculate the average value of the numbers of fail bits obtained during N read operations.

For example, when the difference between the average value of the numbers of fail bits obtained at a time t+2N illustrated in FIG. 9 and the number of fail bits obtained in the read operation by the default read voltage is greater than (or equal to or greater than) the preset threshold, the controller 120 may adopt the second candidate read voltage as a next read voltage. The controller 120 may set the next read voltage as a default read voltage and continuously use the next read voltage in a subsequent read operation.

Since a next read voltage is newly set before a read operation by the controller 120 fails, the failure probability of a read operation may be reduced and the performance of the read operation may be improved.

When the failure of a read operation by a second candidate read voltage occurs during the second mutation operation, the controller 120 may stop the second mutation operation.

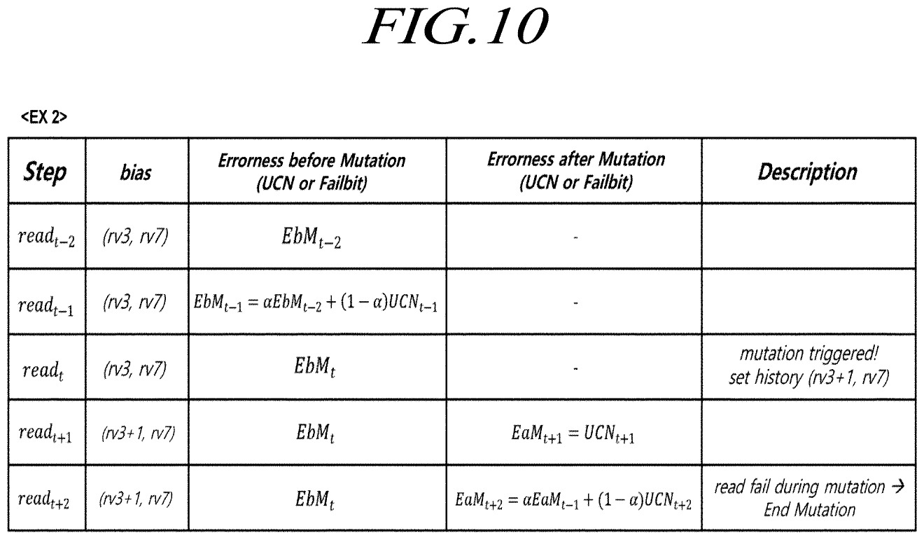

For example, referring to <EX2> of FIG. 8 and FIG. 10, when the condition of the second mutation operation is satisfied, the controller 120 may trigger the second mutation operation.

The controller 120 may perform a read operation using a second candidate read voltage which is obtained as a second offset value is applied. When the read operation by the second candidate read voltage succeeds, the controller 120 may determine whether to adopt the second candidate read voltage as a next read voltage, on the basis of the average value of the numbers of fail bits obtained in N read operations.

When a read operation fails during the second mutation operation, the controller 120 may stop the second mutation operation. The controller 120 may not set a new next read voltage, and may perform a read operation using the existing default read voltage.

When a read operation fails during the second mutation operation, the controller 120 may prevent a read voltage from being unnecessarily changed, thereby preventing the performance of a read operation from deteriorating.

Alternatively, as the case may be, the controller 120 may perform a read operation by setting a latest next read voltage adopted during the second mutation operation as a default read voltage. In this case, when the condition of the second mutation operation is satisfied again during a read operation by the changed default read voltage, the controller 120 may search for a next read voltage while performing the second mutation operation.

According to embodiments of the present disclosure, depending on whether a read operation fails or succeeds, a next read voltage may be searched for using a first candidate read voltage which is obtained as a first offset value is applied or a second candidate read voltage which is obtained as a second offset value is applied.

Since whether to adopt a next read voltage is determined on the basis of an error check node value or the error quantity (e.g., the number of fail bits) obtained in a read operation by the first candidate read voltage or the second candidate read voltage, the possibility of adoption of an optimal next read voltage is increased, and by searching for a next read voltage in advance, the failure probability of a read operation is reduced and the performance of a read operation of the storage device 100 may be improved.

Although various embodiments of the present disclosure have been described with particular specifics and varying details for illustrative purposes, those skilled in the art will appreciate that various modifications, additions and substitutions may be made based on what is disclosed or illustrated in the present disclosure.

What is claimed is:

1. A storage device comprising:
a memory including a plurality of word lines, a plurality of bit lines, and a plurality of memory cells; and
a controller configured to control a read operation on the memory, perform a first mutation operation of searching for a next read voltage using a first candidate read voltage when the read operation fails, and perform a second mutation operation of searching for the next read voltage using a second candidate read voltage when the read operation succeeds, the first candidate read voltage being obtained by applying a first offset value to a default read voltage, the second candidate read voltage being obtained by applying a second offset value to the default read voltage.

2. The storage device according to claim 1, wherein the controller compares, in the first mutation operation, an initial value of a default error check node value with a candidate error check node value, the initial value of the default error check node value indicating an error level when the read operation using the default read voltage fails, the candidate error check node value being obtained in a read operation using the first candidate read voltage, and determines whether to adopt the first candidate read voltage as the next read voltage.

3. The storage device according to claim 2, wherein when the candidate error check node value according to the first candidate read voltage is smaller than the initial value of the default error check node value, the controller adopts the first candidate read voltage as the next read voltage.

4. The storage device according to claim 2, wherein when the candidate error check node value according to the first candidate read voltage that has a first value is equal to or greater than the initial value of the default error check node value, the controller changes the first value of the first candidate read voltage to a second value, and performs the first mutation operation using the first candidate read voltage having the second value that is located opposite to the first value with respect to the default read voltage.

5. The storage device according to claim 2, wherein each of the default error check node value and the candidate error check node value is a value that is determined on the basis of a fail bit for at least one of a plurality of memory cells that respectively correspond to a plurality of error check nodes.

6. The storage device according to claim 1, wherein the controller searches for the next read voltage until a read operation by the first candidate read voltage succeeds while performing the first mutation operation.

7. The storage device according to claim 1, wherein the controller performs, in the second mutation operation, a read operation N (N is an integer satisfying N≥2) times using the second candidate read voltage on a single word line among the plurality of word lines, and determines whether to adopt the second candidate read voltage as the next read voltage.

8. The storage device according to claim 1, wherein when, in the second mutation operation, a difference between the number of default fail bits and the number of candidate fail bits is equal to or greater than a preset threshold, the controller adopts the second candidate read voltage as the next read voltage, the number of default fail bits being obtained when the read operation using the default read voltage succeeds, the number of candidate fail bits being obtained in a read operation using the second candidate read voltage.

9. The storage device according to claim 1, wherein when the number of read operations performed on a single word line among the plurality of word lines is equal to or greater than a preset reference value, the controller performs the second mutation operation.

10. The storage device according to claim 1, wherein when the number of default fail bits is between a preset lower limit value and a preset upper limit value, the controller performs the second mutation operation, the number of default fail bits being obtained when the read operation by the default read voltage succeeds.

11. The storage device according to claim 1, wherein the read operation is a first read operation, and
wherein when a second read operation using the second candidate read voltage fails while performing the second mutation operation, the controller stops the second mutation operation, and performs a third read operation by the default read voltage after stopping the second mutation operation.

12. The storage device according to claim 1, wherein the second offset value is smaller than the first offset value.

13. The storage device according to claim 1, wherein the controller searches for the next read voltage by changing the first offset value at least one time while performing the first mutation operation.

14. A method for operating a storage device, comprising:
performing a first read operation using a default read voltage;
searching for a next read voltage, when the first read operation fails, while performing a second read operation using a first candidate read voltage, the first candidate read voltage being obtained by applying a first offset value to the default read voltage; and
searching for the next read voltage, when the first read operation succeeds, while performing a third read operation using a second candidate read voltage, the second candidate read voltage being obtained by applying a second offset value to the default read voltage.

15. The method according to claim 14, wherein when a candidate error check node value obtained in the second read operation is smaller than an initial value of a default error check node value obtained in the first read operation, the first candidate read voltage used in the second read operation is adopted as the next read voltage.

16. The method according to claim 14, wherein when a difference between the number of default fail bits and the number of candidate fail bits is equal to or greater than a preset threshold, the second candidate read voltage used in the third read operation is adopted as the next read voltage, the number of candidate fail bits being obtained in the third read operation, the number of default fail bits being obtained in the first read operation.

17. The method according to claim 14, wherein the second read operation is repeatedly performed until a read operation using the first candidate read voltages succeeds.

18. The method according to claim 14, wherein when the third read operation using the second candidate read voltage fails, searching for the next read voltage is stopped, and a fourth read operation is performed using the default read voltage.

19. A controller comprising:
a read operation control unit configured to control a first read operation using a default read voltage; and
a next read voltage search unit configured to perform, when the first read operation fails, a second read operation using a first candidate read voltage to search for a next read voltage, the first candidate read voltage being obtained by applying a first offset value to the default read voltage, and perform, when the first read operation succeeds, a third read operation using a second candidate read voltage to search for the next read voltage, the second candidate read voltage being obtained by applying a second offset value to the default read voltage, the second value being smaller than the first offset value.

20. The controller according to claim 19, wherein the next read voltage search unit determines whether to adopt the next read voltage, on the basis of an error check node value obtained in the second read operation, and determines whether to adopt the next read voltage, on the basis of the number of fail bits obtained in the third read operation, and
wherein the error check node value is a value that is determined by fail bits for a plurality of memory cells respectively corresponding to a plurality of error check nodes.
